(19) United States
(12) Patent Application Publication
(10) Pub. No.: US 2019/0088715 A1
(43) Pub. Date: Mar. 21, 2019

(54) MEMORY DEVICE

(71) Applicant: TOSHIBA MEMORY CORPORATION, Tokyo (JP)

(72) Inventors: Kazuhiko YAMAMOTO, Yokkaichi Mie (JP); Yusuke ARAYASHIKI, Yokkaichi Mie (JP); Kana ISHIKAWA, Yokkaichi Mie (JP)

(73) Assignee: TOSHIBA MEMORY CORPORATION, Tokyo (JP)

(21) Appl. No.: 15/909,454

(22) Filed: Mar. 1, 2018

(30) Foreign Application Priority Data
Sep. 20, 2017 (JP) 2017-180291

(51) Int. Cl. H01L 27/24; H01L 45/00; G11C 13/00

(52) U.S. Cl. CPC H01L 27/249; G11C 2213/71; H01L 45/146; H01L 45/08; H01L 45/1616; H01L 45/1233; H01L 45/1246; G11C 13/0007; G11C 2213/52; H01L 45/1625; G11C 13/0069; G11C 2013/009; G11C 13/0097; G11C 13/0028; G11C 13/004; G11C 2213/32; G11C 2213/55; H01L 45/1253

(57) ABSTRACT

A memory device includes a first conductive layer, a second conductive layer, and a variable resistance layer disposed between the first and second conductive layers. The variable resistance layer includes a first layer containing a semiconductor or a first metal oxide, a second layer disposed between the first layer and the first conductive layer, and containing a second metal oxide, and a first amorphous layer disposed between the second layer and the first conductive layer.

### CROSS-REFERENCE TO RELATED APPLICATION

This application claims the benefit of and priority to Japanese Patent Application No. 2017-180291, filed Sep. 20, 2017, the entire contents of which are incorporated herein by reference.

### FIELD

Embodiments described herein relate generally to a memory device.

### BACKGROUND

In a resistance-change type memory, a current flows by applying a voltage to a variable resistance layer of a memory cell to make a transition between a high resistance state and a low resistance state. For example, when the high resistance state is defined as data “0” and the low resistance state is defined as data “1”, the memory cell can store 1-bit data of “0” and “1”. In order to guarantee the reliability of the resistance-change type memory, the memory cell is required to maintain its characteristics even if the memory cell repeatedly transitions between the high resistance state and the low resistance state.

### DESCRIPTION OF THE DRAWINGS

FIG. 1 is a schematic cross-sectional view of a memory cell of a memory device according to a first embodiment;

FIG. 2 is a block diagram of the memory device according to the first embodiment;

FIG. 3 is a schematic cross-sectional view of a memory cell of a memory device according to a second embodiment;

FIG. 4 is a schematic cross-sectional view of a memory cell of a memory device according to a modification of the second embodiment;

FIG. 5 is a block diagram of a memory device according to a third embodiment;

FIG. 6 is an equivalent circuit diagram of a memory cell array according to the third embodiment; and

FIGS. 7A and 7B are schematic cross-sectional views of the memory cell array of the memory device according to the third embodiment.

### DETAILED DESCRIPTION

Some embodiments provide a memory device capable of improving reliability.

According to some embodiments, a memory device includes: a first conductive layer; a second conductive layer; and a variable resistance layer that is provided between the first and second conductive layers. In the memory device, the variable resistance layer may include: a first layer containing a semiconductor or a first metal oxide; a second layer that is provided between the first layer and the first conductive layer, and containing a second metal oxide; and a first amorphous layer that is provided between the second layer and the first conductive layer.

Hereafter, embodiments of the disclosure will be described with reference to the accompanying drawings. In the following description, the same or similar components will be represented by like reference numerals, and the descriptions of components which have been described once will be properly omitted.

In the specification, the terms such as ‘upper’ and ‘lower’ are used for convenience of description. The terms such as ‘upper’ and ‘lower’ only indicate a relative positional relation in the drawings, and do not define a positional relation in the direction of gravity.

The qualitative analysis and quantitative analysis for chemical compositions of members constituting a memory device in the specification can be performed through SIMS (Secondary Ion Mass Spectroscopy) and EDX (Energy Dispersive X-ray Spectroscopy), for example. Moreover, the thicknesses of members constituting a semiconductor device and a distance between members can be measured through a TEM (Transmission Electron Microscope). Furthermore, whether a member constituting the memory device is amorphous can be determined by checking whether grains are present in the member, through observation with the TEM.

Hereafter, memory devices according to some embodiments will be described with reference to the drawings.

### First Embodiment

A memory device according to a first embodiment includes: a first conductive layer; a second conductive layer; and a variable resistance layer that is provided between the first and second conductive layers. The variable resistance layer includes: a first layer containing a semiconductor or a first metal oxide; a second layer that is provided between the first layer and the first conductive layer, and containing a second metal oxide; and a first amorphous layer that is provided between the second layer and the first conductive layer.

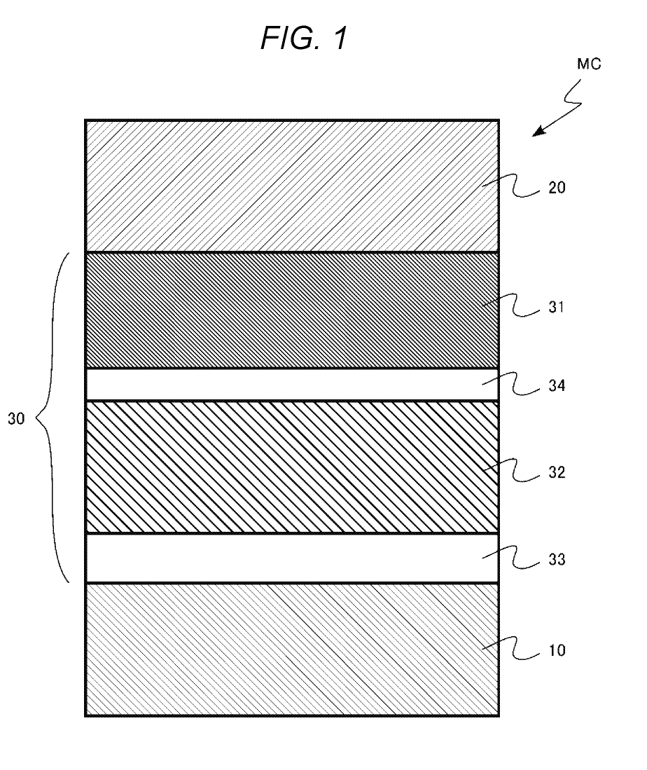

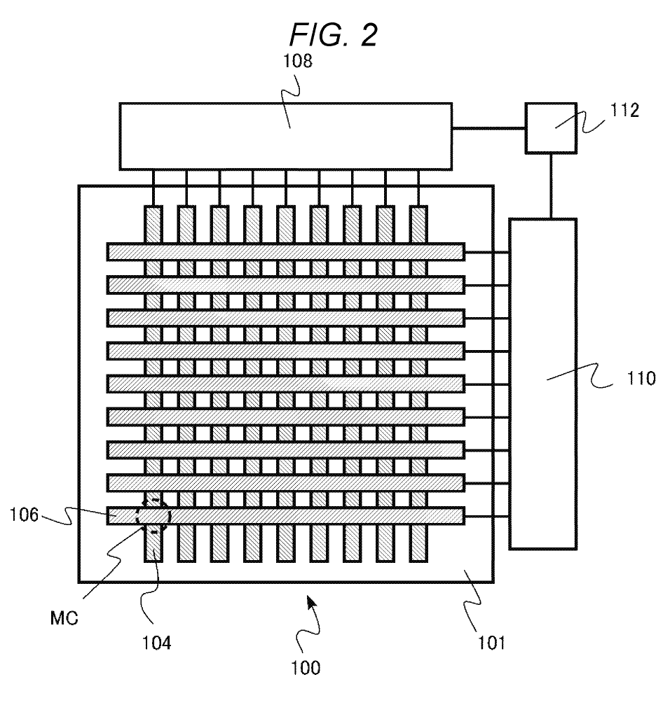

FIG. 1 is a schematic cross-sectional view of a memory cell MC of the memory device according to the first embodiment. FIG. 2 is a block diagram illustrating a memory cell array 100 and peripheral circuits in the memory device according to the first embodiment. FIG. 1 illustrates a cross-section of one memory cell MC indicated by a dotted circle in the memory cell array 100 of FIG. 2.

The memory cell array 100 of the memory device according to the first embodiment may include, for example, a plurality of word lines 104 and a plurality of bit lines 106 on a semiconductor substrate 101 with an insulating layer interposed therebetween, the plurality of bit lines 106 intersecting with the plurality of word lines 104. The bit lines 106 are provided at an upper layer of the word lines 104. Around the memory cell array 100, a first control circuit 108, a second control circuit 110, and a sense circuit 112 are provided as the peripheral circuits.

At respective intersections between the word lines 104 and the bit line 106, a plurality of memory cells MC are provided. The memory device according to the first embodiment is a resistance-change type memory with a cross point structure. The memory cell MC is a two-terminal variable resistance element.

The plurality of word lines 104 are connected to the first control circuit 108, respectively. The plurality of bit lines 106 are connected to the second control circuit 110, respectively. The sense circuit 112 is connected to the first and second control circuits 108 and 110.

The first and second control circuits 108 and 110 have functions of selecting a desired memory cell MC, writing data to the memory cell MC, reading data from the memory cell MC, and erasing the data of the memory cell MC, for example. During the read operation, the data of the memory cell is read as the amount of current flowing between the word line 104 and the bit line 106. The sense circuit 112 has a function of determining the current amount and determining the polarity of the data. For example, the sense circuit 112 determines “0” and “1” of data.

The first control circuit 108, the second control circuit 110, and the sense circuit 112 may be configured with electronic circuits using a semiconductor device formed on the semiconductor substrate 101, for example.

As illustrated in FIG. 1, the memory cell MC includes a lower electrode (first conductive layer) 10, a upper electrode (second conductive layer) 20, and a variable resistance layer 30.

The lower electrode 10 is connected to the word line 104. The lower electrode 10 is formed of a metal. For example, the lower electrode 10 may be formed of titanium nitride (TiN) or tungsten (W) . The lower electrode 10 itself may serve as the word line 104.

The upper electrode 20 is connected to the bit line 106. The upper electrode 20 is formed of a metal . For example, the upper electrode 20 may be formed of titanium nitride (TiN) or tungsten (W). The upper electrode 20 itself may serve as the bit line 106.

The variable resistance layer 30 is provided between the lower electrode 10 and the upper electrode 20. The variable resistance layer 30 includes a high resistance layer (first layer) 31, a low resistance layer (second layer) 32, a first amorphous layer 33, and a second amorphous layer 34.

The variable resistance layer 30 has a structure in which the first amorphous layer 33, the low resistance layer 32, the second amorphous layer 34, and the high resistance layer 31 are sequentially arranged from the lower electrode 10 toward the upper electrode 20. The high resistance layer 31, the second amorphous layer 34, the low resistance layer 32, and the first amorphous layer 33 may be sequentially arranged from the lower electrode 10 toward the upper electrode 20.

The variable resistance layer 30 may have a thickness of 5 nm or more and 25 nm or less, for example. The variable resistance layer 30 may be formed through ALD (Atomic Layer Deposition), for example. However, the variable resistance layer 30 may be formed through CVD (Chemical Vapor Deposition) or sputtering.

The high resistance layer 31 contains a semiconductor or a first metal oxide. The high resistance layer 31 may be an amorphous semiconductor or amorphous metal oxide, for example.

The high resistance layer 31 may be a semiconductor, for example. The high resistance layer 31 may be silicon, germanium, tin, or a compound thereof. The high resistance layer 31 may be amorphous silicon, amorphous germanium, amorphous silicon germanium, amorphous silicon tin, or amorphous germanium tin. Compounds thereof may be formed as a plurality of stacked bodies. The high resistance layer 31 may be crystallized.

The high resistance layer 31 is formed of the first metal oxide, for example. The first metal oxide may contain at least one metal element selected from the group consisting of aluminum (Al), hafnium (Hf), zirconium (Zr), tantalum (Ta), niobium (Nb), and vanadium (V). For example, the high resistance layer 31 may be formed of aluminum oxide, hafnium oxide, zirconium oxide, tantalum oxide, niobium oxide, vanadium oxide, or compounds thereof.

The high resistance layer 31 may have a thickness of 1 nm or more and 10 nm or less, for example.

The low resistance layer 32 is provided between the high resistance layer 31 and the lower electrode 10.

The low resistance layer 32 may contain a second metal oxide. The second metal oxide may contain at least one metal element selected from the group consisting of titanium (Ti), niobium (Nb), tantalum (Ta), and tungsten (W). The low resistance layer 32 may be formed of titanium oxide, niobium oxide, tantalum oxide, or tungsten oxide, for example. The second metal oxide is different from the first metal oxide. The low resistance layer 32 may contain the same kind of metal oxide as the high resistance layer 31, the metal oxide having different electrical resistance from the high resistance layer 31. For example, the high resistance layer 31 may be formed of amorphous titanium oxide, and the low resistance layer 32 may be formed of crystalline titanium oxide.

The low resistance layer 32 has resistivity lower than that of the high resistance layer 31. At least a part of the low resistance layer 32 has a crystalline structure.

The low resistance layer 32 may have, for example, a polycrystalline structure. The resistivity is lowered by crystallization of the second metal oxide of the low resistance layer 32. The metal oxide of the low resistance layer 32 has a crystallization ratio higher than that of the first metal oxide of the high resistance layer 31. The crystallization ratio of the metal oxide can be measured using, for example, TEM.

The low resistance layer 32 may have a thickness of 3 nm or more and 15 nm or less, for example.

The first amorphous layer 33 is provided between the low resistance layer 32 and the lower electrode 10. The first amorphous layer 33 is amorphous. The first amorphous layer 33 maybe formed of an oxide, a nitride, or an oxynitride, for example.

The first amorphous layer 33 may contain a third metal oxide, for example. The third metal oxide contains at least one metal element selected from the group consisting of aluminum (Al), hafnium (Hf), zirconium (Zr), tantalum (Ta), lanthanum (La), and niobium (Nb). The first amorphous layer 33 may be formed of aluminum oxide, hafnium oxide, zirconium oxide, lanthanum oxide, tantalum oxide, or niobium oxide, for example. The first amorphous layer 33 may include an alloy film of metal elements or a stacked film of metal oxides.

For example, the standard Gibbs energy of the third metal oxide contained in the first amorphous layer 33 is smaller than the standard Gibbs energy of the second metal oxide contained in the low resistance layer 32. For example, when the second metal oxide is titanium oxide, aluminum oxide, hafnium oxide, zirconium oxide or lanthanum oxide, which has smaller standard Gibbs energy than the second metal oxide, can be applied as the third metal oxide.

The first amorphous layer 33 may be formed of an oxide, a nitride, or an oxynitride containing at least one element selected from the group consisting of silicon (Si), and germanium (Ge), for example. The first amorphous layer 33 may be formed of silicon oxide, germanium oxide, silicon nitride, germanium nitride, silicon oxynitride, or germanium oxynitride, for example.

The first amorphous layer 33 may be formed of a metal oxide or a metal oxynitride containing silicon (Si) and a metal element, for example. The first amorphous layer 33 may be formed of aluminum silicate, hafnium silicate, nitrogen-added aluminum silicate, or nitrogen-added hafnium silicate, for example.

The first amorphous layer 33 may be formed of a metal nitride or a metal oxynitride, for example. The first amorphous layer 33 is formed of aluminum nitride, hafnium nitride, aluminum oxynitride, or hafnium oxynitride, for example.

The first amorphous layer 33 has a different composition from the high resistance layer 31 and the low resistance layer 32. The first amorphous layer 33 has a function of preventing diffusion of atoms between the high resistance layer 31 and the low resistance layer 32. Furthermore, the first amorphous layer 33 has a function of absorbing oxygen from the low resistance layer 32.

The first amorphous layer 33 may have a thickness of 0.2 nm or more and 3 nm or less, for example.

The second amorphous layer 34 is provided between the high resistance layer 31 and the low resistance layer 32. The second amorphous layer 34 is amorphous. The second amorphous layer 34 may be formed of an oxide, a nitride, or an oxynitride, for example.

The second amorphous layer 34 may be formed of an oxide, a nitride, or an oxynitride containing at least one element selected from the group consisting of aluminum (Al), silicon (Si), germanium (Ge), zirconium (Zr),and hafnium (Hf), for example. The second amorphous layer 34 may be formed of aluminum oxide, silicon oxide, germanium oxide, zirconium oxide, hafnium oxide, aluminum nitride, silicon nitride, germanium nitride, aluminum oxynitride, silicon oxynitride, germanium oxynitride, zirconium oxynitride, or hafnium oxynitride, for example. The second amorphous layer 34 may include an alloy film of the above-described materials. Moreover, the second amorphous layer 34 may have a structure in which two or more kinds of films among the above-described films are stacked.

The second amorphous layer 34 has a different composition from the high resistance layer 31 and the low resistance layer 32. The second amorphous layer 34 has a function of preventing a reaction between the high resistance layer 31 and the low resistance layer 32.

The second amorphous layer 34 may have a thickness of 0.2 nm or more and 1 nm or less, for example.

When a voltage is applied to the variable resistance layer 30 to pass a current, the variable resistance layer 30 changes into a low resistance state from a high resistance state, or changes into a high resistance state from a low resistance state. The change into the low resistance state from the high resistance state is referred to as a set operation, for example. The change into the high resistance state from the low resistance state is referred to as a reset operation, for example. A voltage applied to the variable resistance layer 30 during the change into the low resistance state from the high resistance state is referred to as a set voltage, and a voltage applied to the variable resistance layer 30 during the change into the high resistance state from the low resistance state is referred to as a reset voltage.

The oxygen deficiency amount (the quantity of oxygen vacancies) in the low resistance layer 32 changes due to the voltage applied to the variable resistance layer 30. As the oxygen deficiency amount or the oxygen deficiency distribution in the low resistance layer 32 changes, the conductivity of the variable resistance layer 30 changes. The low resistance layer 32 is a so-called vacancy modulated conductive oxide.

For example, the high resistance state is defined as data “0”, and the low resistance state is defined as data “1”. The memory cell MC can store 1-bit data of “0” or “1”.

The operation and effect of the memory device according to the first embodiment will be described.

In the resistance-change type memory which changes the conductivity of the variable resistance layer 30 using a change in the oxygen deficiency amount, the characteristics of the memory cell MC maybe degraded due to repetition of the set operation and the reset operation. Specifically, for example, a resistance ratio between the high resistance state and the low resistance state becomes small. When the resistance ratio between the high resistance state and the low resistance state becomes small, read margin of data from the memory cell MC decreases, which is a problem.

For example, there is a method of increasing the set voltage or the reset voltage depending on the number of repetitions of the set operation and the reset operation in order to compensate for decrease in read margin of data. However, when the set voltage or the reset voltage becomes too high, dielectric breakdown of the variable resistance layer 30 occurs and the memory cell MC does not operate.

Therefore, it is required to prevent the degradation in characteristic of the memory cell MC and to improve the reliability of the resistance-change type memory.

In the memory device according to the first embodiment, the first amorphous layer 33 is provided between the low resistance layer 32 and the lower electrode 10. The formation of the first amorphous layer 33 prevents degradation in characteristic of the memory cell MC.

The reason why the formation of the first amorphous layer 33 prevents the degradation in characteristic of the memory cell MC is considered as follows. If the first amorphous layer 33 is not present, the constituent atoms of the lower electrode 10 may be diffused into the low resistance layer 32 or the high resistance layer 31 through the grain boundary of the low resistance layer 32, while the set and reset operations are repeated. For example, when the lower electrode 10 is formed of titanium nitride, titanium, or nitrogen atoms which are the constituent atoms of the titanium nitride are diffused into the low resistance layer 32 or the high resistance layer 31. The diffusion of the constituent atoms of the lower electrode 10 into the low resistance layer 32 or the high resistance layer 31 is considered as one of factors causing the degradation in characteristic of the memory cell MC.

The first amorphous layer 33 has an amorphous state with no grain boundary. When the first amorphous layer 33 is provided, it is possible to prevent the diffusion of the constituent atoms of the lower electrode 10 into the low resistance layer 32 or the high resistance layer 31. Thus, the first amorphous layer 33 is provided to prevent the degradation in characteristic of the memory cell MC. Therefore, the reliability of the resistance-change type memory is improved. Furthermore, when the first amorphous layer 33 is provided, it is possible to remove the unevenness or crystal orientation of the lower electrode metal. Therefore, the density of the grain boundary of the low resistance layer 32 is reduced. The reduction in density of the grain boundary of the low resistance layer 32 can prevent the diffusion of the constituent atoms of the lower electrode 10 into the low resistance layer 32 or the high resistance layer 31. From such a viewpoint, the degradation in characteristic of the memory cell MC is prevented, while the reliability of the resistance-change type memory is improved.

The first amorphous layer 33 may have a thickness of 0.2 nm or more and 3 nm or less, for example. More preferably, the first amorphous layer 33 may have a thickness of 1 nm or less. When the thickness of the first amorphous layer 33 is less than the range, the diffusion prevention effect for the constituent atoms of the lower electrode 10 may be reduced. Moreover, when the thickness of the first amorphous layer 33 exceeds the range, the resistance of the first amorphous layer 33 may be increased to disturb the mobility of carriers. Furthermore, when the thickness of the first amorphous layer 33 exceeds the range, the first amorphous layer 33 may be crystallized, and the diffusion prevention effect for the constituent atoms of the lower electrode 10 may not appear.

The first amorphous layer 33 may have the third metal oxide, and the standard Gibbs energy of the third metal oxide may be set to a smaller value than the standard Gibbs energy of the second metal oxide forming the low resistance layer 32. The above-described structure can further prevent the degradation in characteristic of the memory cell MC.

The reason why the degradation in characteristic of the memory cell MC is prevented by the above-described structure is considered as follows. When the set and reset operations are repeated, the oxygen deficiency density of the low resistance layer 32 is reduced, and the reduction is considered as one of factors that degrade the characteristic of the memory cell MC.

Since the standard Gibbs energy of the third metal oxide is smaller than that of the second metal oxide, the third metal oxide is more thermally stable than the second metal oxide. Therefore, the third metal oxide forming the first amorphous layer 33 has a function of absorbing oxygen from the second metal oxide forming the low resistance layer 32. Thus, a reduction in oxygen deficiency density of the low resistance layer 32 is prevented. Accordingly, the reliability of the resistance-change type memory is improved.

From the aspect that the standard Gibbs energy of the third metal oxide forming the first amorphous layer 33 is smaller than the standard Gibbs energy of the second metal oxide forming the low resistance layer 32, titanium oxide may be used as the second metal oxide, and aluminum oxide, hafnium oxide, zirconium oxide or lanthanum oxide may be used as the third metal oxide.

The first amorphous layer 33 may be formed of aluminum oxide or hafnium oxide, in order to facilitate the film forming process, raise the stability of the layer, and improve the diffusion prevention effect for the constituent atoms of the lower electrode 10.

In order to prevent the degradation in characteristic of the memory cell MC, a metal oxide containing two or more kinds of metal elements may be used as the third metal oxide of the first amorphous layer 33. The third metal oxide may be a metal oxide containing titanium and aluminum, for example. Since the third metal oxide contains two or more kinds of metal elements, the third metal oxide can maintain the function of absorbing oxygen and easily maintain the amorphous state even if the third metal oxide is subjected to a high temperature process.

The second amorphous layer 34 may have a thickness of 0.2 nm or more and 1 nm or less, for example. When the thickness of the second amorphous layer 34 is less than the range, the function of preventing a reaction between the high resistance layer 31 and the low resistance layer 32 may be reduced. Furthermore, when the thickness of the second amorphous layer 34 exceeds the range, the resistance of the second amorphous layer 34 may be increased to disturb the mobility of carriers.

In order to facilitate the film formation process, raise the stability of the layer, and effectively prevent a reaction between the high resistance layer 31 and the low resistance layer 32, aluminum oxide may be used as the second amorphous layer 34.

The second amorphous layer 34 may have a stacked structure of two or more type of metal oxide films selected from aluminum oxide, hafnium oxide, and zirconium oxide. More desirably, the stacked structure may include aluminum oxide. The aluminum oxide has a high crystallization temperature, and easily maintains the amorphous state. Furthermore, since the bond between zirconium oxide or hafnium oxide and oxygen is weaker than the bond between aluminum oxide and oxygen, oxygen can be inserted and extracted more easily. The stacked structure can improve the endurance (data rewrite) characteristic of the memory cell MC.

The stacked structure may include two or three or more metal oxide films. In order to form a plate-shaped film while preventing an island shape, a small number of metal oxide films, that is, two metal oxide films may be stacked. Furthermore, in order to improve the endurance (data rewrite) characteristic of the memory cell MC, three metal oxide films maybe stacked. More desirably, three or more metal oxide films may be stacked.

The high resistance layer 31 may be formed of amorphous silicon, in order to facilitate the film forming process, raise the stability of the layer, and optimize the resistance value of the variable resistance layer 30.

The low resistance layer 32 may be formed of titanium oxide, in order to facilitate the film forming process, raise the stability of the layer, and increase the resistance ratio of the high resistance state to the low resistance state in the variable resistance layer 30.

In the first embodiment, the second amorphous layer 34 is formed in the variable resistance layer 30. For example, however, when materials having a low reactivity are used as the materials of the high resistance layer 31 and the low resistance layer, the second amorphous layer 34 may not be formed in the variable resistance layer 30.

According to the first embodiment, the diffusion of the constituent atoms of the lower electrode 10 into the low resistance layer 32 or the high resistance layer 31 is prevented, and the degradation in characteristic of the memory cell MC is prevented. Therefore, the reliability of the memory device can be improved.

### Second Embodiment

A memory device according to a second embodiment has the same structure as the memory device according to the first embodiment, except that the first amorphous layer 33 has a stacked structure of two or more kinds of metal oxide films. Hereinafter, the descriptions of the same contents as those of the first embodiment are omitted herein.

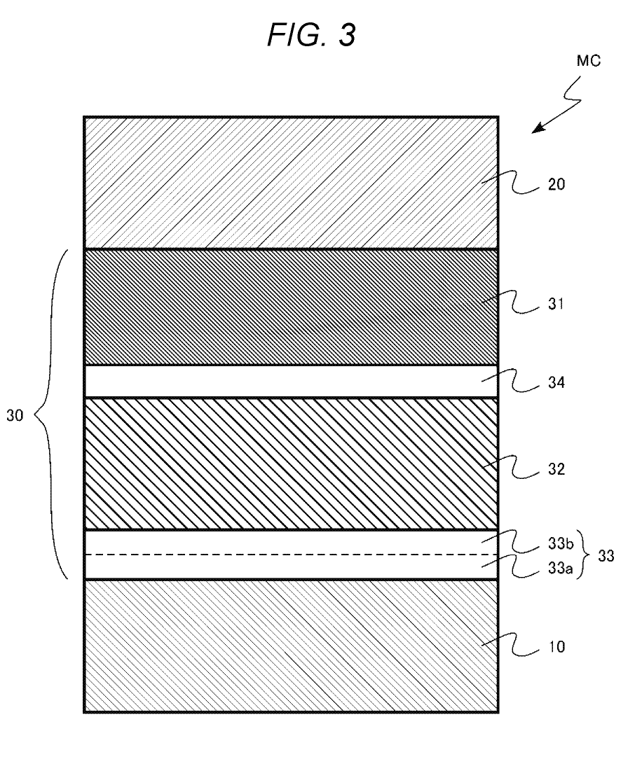

FIG. 3 is a schematic cross-sectional view of a memory cell MC of the memory device according to the second embodiment.

The first amorphous layer 33 has a stacked structure of a titanium oxide film (first metal oxide film) 33a and an aluminum oxide film (second metal oxide film) 33b.

Since the first amorphous layer 33 has a stacked structure of two kinds of metal oxide films, a degradation in characteristic of the memory cell MC is further prevented.

The reason why the stacked structure of two kinds of metal oxide films in the first amorphous layer 33 further prevents the degradation in characteristic of the memory cell MC is considered as follows. When the first amorphous layer 33 has a stacked structure of two or more kinds of metal oxide films, the oxygen deficiency density of the first amorphous layer 33 is increased. With the increase of the oxygen deficiency density, the third metal oxide can more effectively absorb oxygen from the second metal oxide forming the low resistance layer 32. Therefore, a reduction in oxygen deficiency density of the low resistance layer 32 is prevented, which makes it possible to further prevent the degradation in characteristic of the memory cell MC. Accordingly, the reliability of the resistance-change type memory is further improved.

In particular, when the low resistance layer 32 is formed over the first amorphous layer 33 during a process of fabricating the memory cell MC, the surface roughness of the first amorphous layer 33 is considered to determine the crystallinity of the low resistance layer 32. That is, when the first amorphous layer 33 has high surface roughness, the crystallinity of the low resistance layer 32 is degraded. Then, the crystal size of the low resistance layer 32 is decreased while the grain boundary of the low resistance layer 32 is increased, thereby degrading the characteristic of the memory cell MC. When the first amorphous layer 33 has a stacked structure of two kinds of metal oxide films, the surface roughness of the first amorphous layer 33 is reduced. Furthermore, since the orientation of the base film is removed, the crystallinity of the low resistance layer 32 is improved, and a degradation in characteristic of the memory cell MC is prevented.

### Modification

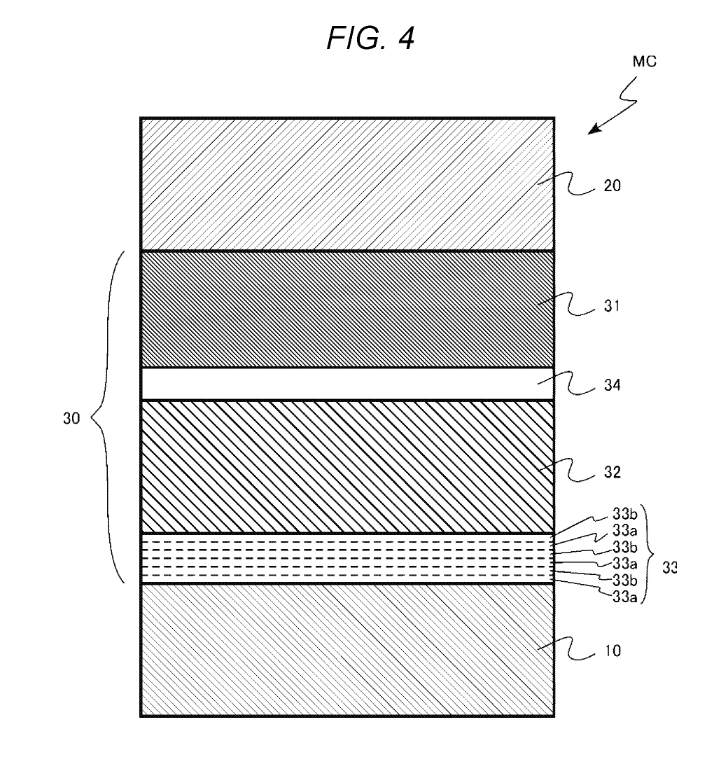

FIG. 4 is a schematic cross-sectional view of a memory cell MC of a memory device according to a modification of the second embodiment. The first amorphous layer 33 has a stacked structure in which three titanium oxide films (first metal oxide films) 33a and three aluminum oxide films (second metal oxide films) 33b are alternately stacked.

In the modification, when the low resistance layer 32 is formed over the first amorphous layer 33, the first amorphous layer 33 has lower surface roughness than in the second embodiment. Thus, a degradation in characteristic of the memory cell MC is further prevented. Therefore, the reliability of the resistance-change type memory is further improved.

The first amorphous layer 33 may have a stacked structure of three or more kinds of metal oxide films.

According to the modification, the degradation in characteristic of the memory cell MC is further prevented as compared to the first embodiment. Therefore, the reliability of the memory device can be further improved.

### Third Embodiment

A memory device according to a third embodiment has the same structure as the first or second embodiment, except that the memory cell array has a three-dimensional structure. Therefore, the descriptions of the same contents as those of the first or second embodiment are omitted herein.

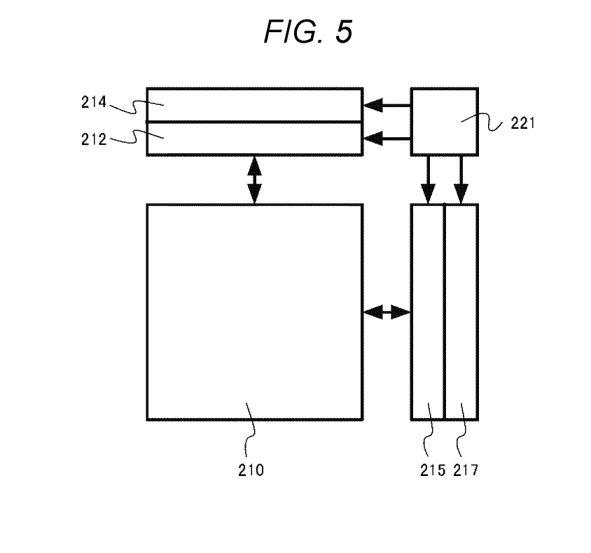

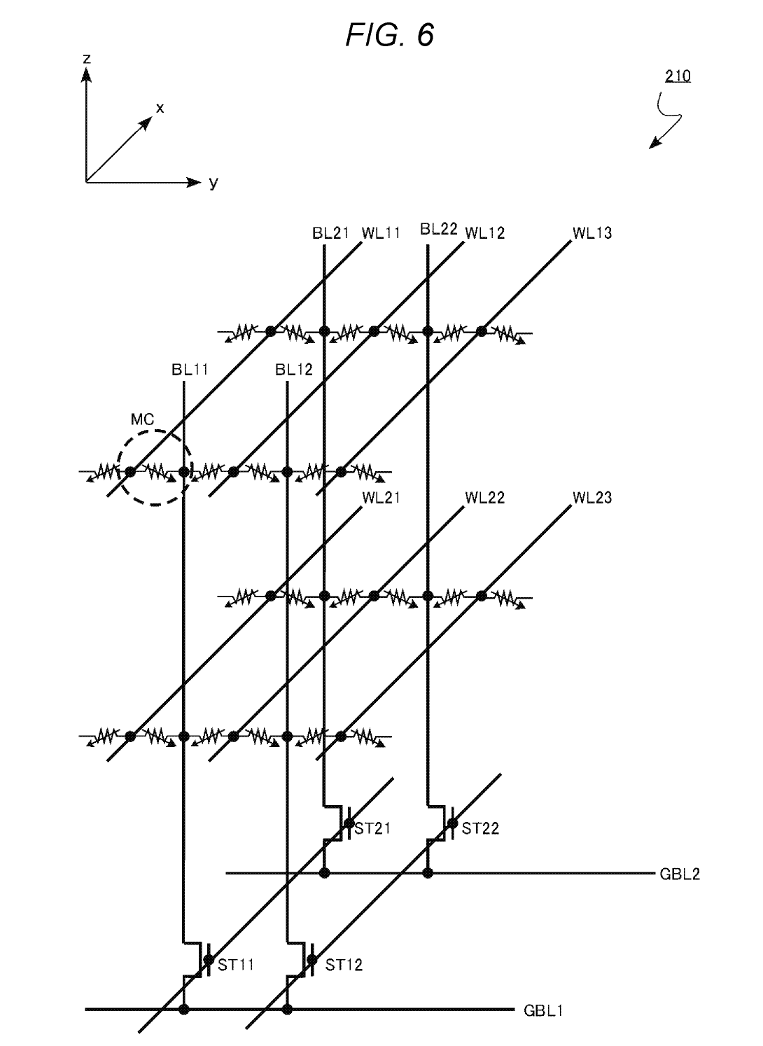

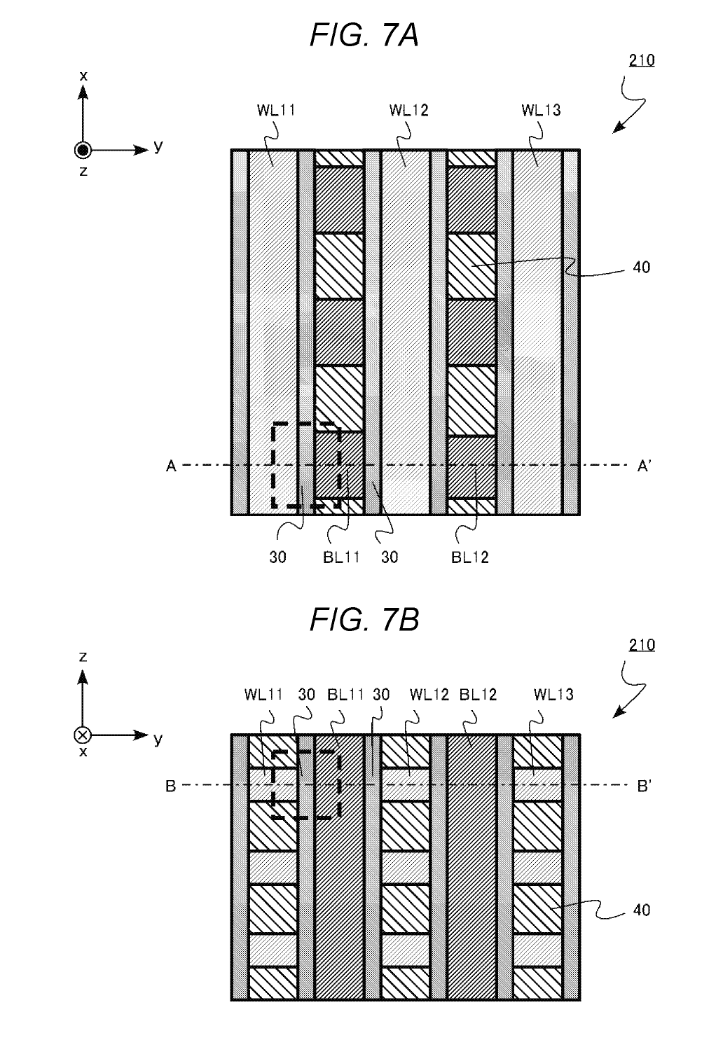

FIG. 5 is a block diagram of the memory device according to the third embodiment. FIG. 6 is an equivalent circuit diagram of the memory cell array. FIGS. 7A and 7B schematically illustrate a wiring structure in the memory cell array.

The memory cell array according to the third embodiment has a three-dimensional structure in which memory cells MC are three-dimensionally arranged.

As illustrated in FIG. 5, the memory device includes a memory cell array 210, a word line driver circuit 212, a row decoder circuit 214, a sense amplifier 215, a column decoder circuit 217, and a control circuit 221.

Furthermore, as illustrated in FIG. 6, the memory cell array 210 includes a plurality of memory cells MC which are three-dimensionally arranged. In FIG. 6, a region surrounded by a dashed line corresponds to one memory cell MC.

The memory cell array 210 includes a plurality of word lines WL (WL11, WL12, WL13, WL21, WL22, and WL23) and a plurality of bit lines BL (BL11, BL12, BL21, and BL22). The word lines WL extend in an x-direction. The bit lines BL extend in a z-direction. The word lines WL and the bit lines BL intersect with each other at a right angle. The memory cells MC are arranged at the respective intersections between the word lines WL and the bit lines BL.

The plurality of word lines WL is electrically connected to the row decoder circuit 214. The plurality of bit lines BLs is connected to the sense amplifier 215. Between the plurality of bit lines BL and the sense amplifier 215, select transistors ST (ST11, ST21, ST12, and ST22) and global bit lines GBL (GBL1 and GBL2) are installed.

The row decoder circuit 214 has a function of selecting a word line WL according to an input row address signal. The word line driver circuit 212 has a function of applying a predetermined voltage to the word line WL selected by the row decoder circuit 214.

The column decoder circuit 217 has a function of selecting a bit line BL according to an input column address signal. The sense amplifier 215 has a function of applying a predetermined voltage to the bit line BL selected by the column decoder circuit 217. Furthermore, the sense amplifier 215 has a function of sensing and amplifying a current flowing between the selected word line WL and the selected bit line BL.

The control circuit 221 has a function of controlling the word line driver circuit 212, the row decoder circuit 214, the sense amplifier 215, the column decoder circuit 217, and other circuits (not illustrated).

The word line driver circuit 212, the row decoder circuit 214, the sense amplifier 215, the column decoder circuit 217, the control circuit 221 and the like include transistors or wiring layers using semiconductor layers (not illustrated), for example.

FIGS. 7A and 7B are schematic cross-sectional views of the memory cell array 210 of the memory device according to the third embodiment. FIG. 7A is a cross-sectional view of the memory cell array 210 taken along an x-y direction. FIG. 7B is a cross-sectional view of the memory cell array 210 taken along a y-z direction. FIG. 7A is a cross-sectional view taken along a line B-B′ of FIG. 7B, and FIG. 7B is a cross-sectional view taken along a line A-A′ of FIG. 7A. In FIGS. 7A and 7B, a region surrounded by a dashed line indicates one memory cell MC.

The memory cell array 210 includes the word line WL11, the word line WL12, the word line WL13, the bit line BL11, and the bit line BL12. Furthermore, the memory cell array 210 includes the variable resistance layer 30 and an interlayer dielectric layer 40.

The variable resistance layer 30 according to the first or second embodiment is applied as the variable resistance layer 30.

According to the third embodiment, the memory device has a three-dimensional structure to improve the degree of integration thereof, in addition to the effect of the first or second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A memory device comprising:
a first conductive layer;
a second conductive layer; and
a variable resistance layer disposed between the first and second conductive layers, wherein
the variable resistance layer comprises:
a first layer comprising a semiconductor or a first metal oxide;
a second layer disposed between the first layer and the first conductive layer, and comprising a second metal oxide;
a first amorphous layer disposed between the second layer and the first conductive layer; and
a second amorphous layer disposed between the first layer and the second layer.

2. The memory device according to claim 1, wherein the first amorphous layer comprises an oxide, a nitride, or an oxynitride.

3. The memory device according to claim 1, wherein the first amorphous layer comprises a third metal oxide that comprises two or more metal elements.

4. The memory device according to claim 1, wherein the first amorphous layer has a stacked structure of two or more metal oxide films.

5. (canceled)

6. The memory device according to claim 1, wherein the second amorphous layer is formed of an oxide, a nitride, or an oxynitride.

7. The memory device according to claim 6, wherein the second amorphous layer has a stacked structure of two or more metal oxide films selected from the group consisting of aluminum oxide, hafnium oxide, and zirconium oxide.

8. The memory device according to claim 1, wherein the first layer has a resistivity higher than that of the second layer.

9. The memory device according to claim 1, wherein the first amorphous layer comprises a third metal oxide, and a standard Gibbs energy of the third metal oxide is smaller than a standard Gibbs energy of the second metal oxide.

10. The memory device according to claim 1, wherein the first layer does not include atoms of the second layer.

11. The memory device according to claim 1, wherein the first amorphous layer is arranged to absorb oxygen from the first layer.

12. The memory device according to claim 1, wherein the second amorphous layer does include atoms of the first or second layers.

13. The memory device according to claim 1, wherein the first amorphous layer has a thickness 0.2 nm to 3 nm.

14. The memory device according to claim 1, wherein the memory device comprises memory cells that are three-dimensionally arranged.

15. A memory device comprising:
a first conductive layer;
a second conductive layer; and
a variable resistance layer disposed between the first and second conductive layers, wherein
the variable resistance layer comprises:
a first layer having a first resistivity;
a second layer having a second resistivity that is higher than the first resistivity;
a first amorphous layer disposed between the first conductive layer and the second conductive layer, and
a second amorphous layer disposed between the first layer and the second layer.

16. The memory device of claim 15, further comprising:
wherein the first amorphous layer is disposed between the first layer and the first conductive layer.

17. A method of making a memory device comprising:
forming a first conductive layer;
forming a second conductive layer; and
forming a variable resistance layer between the first and second conductive layers, wherein
the variable resistance layer comprises:
a first layer comprising a semiconductor or a first metal oxide;
a second layer disposed between the first layer and the first conductive layer, and comprising a second metal oxide;
a first amorphous layer disposed between the second layer and the first conductive layer; and
a second amorphous layer disposed between the first layer and the second layer.

18. The method according to claim 17, wherein the first amorphous layer comprises an oxide, a nitride, or an oxynitride.

19. The method according to claim 17, wherein the first amorphous layer comprises a third metal oxide that comprises two or more metal elements.

20. The method according to claim 17, wherein the first amorphous layer has a stacked structure of two or more metal oxide films.
